(19) United States
(12) Patent Application Publication
(10) Pub. No.: US 2024/0268065 A1
(43) Pub. Date: Aug. 8, 2024

(54) DETECTING ABNORMAL OPERATION OF A FAN COOLING A PROCESSOR AND ADJUSTING PROTECTION TEMPERATURES

(71) Applicant: ADVANCED MICRO DEVICES, INC., SANTA CLARA, CA (US)

(72) Inventors: ZHENGDONG YANG, SUZHOU (CN); JIANMING JIN, SHANGHAI (CN); JIALUEN CHANG, SUZHOU (CN); JUN REN, SUZHOU (CN)

(21) Appl. No.: 18/163,441

(22) Filed: Feb. 2, 2023

(51) Int. Cl. H05K 7/20; G06F 1/20

(52) U.S. Cl. CPC H05K 7/2019; G06F 1/206; H05K 7/20209

(57) ABSTRACT

A device includes a fan and a processor coupled to the fan. The processor includes a system management unit configured to detect abnormal operation of the fan in response to a speed of the fan satisfying one or more conditions. When the system management unit detects abnormal operation of the fan, the system management unit reduces one or more protection temperatures including a throttling temperature and a shut-off temperature.

### BACKGROUND

During operation, one or more target operating temperatures are maintained for a processor. For example, a processor has a target operating temperature and one or more temperature limits. The target operating temperature specifies a temperature at which the processor operates to provide optimal performance for one or more processing tasks. A temperature limit specifies a temperature of the processor that, when reached, causes a reduction in processor functionality to prevent temperature-induced damage to the processor. Additionally, the temperature limit prevents the processor from increasing a temperature of a circuit board to which the processor is mounted to unsafe levels. While conventional processors provide instructions to a fan for cooling the processor, the control signals are based on the processor's temperature and do not account for how the fan responds to the control signals, limiting effectiveness of the fan in cooling the processor.

### BRIEF DESCRIPTION OF THE DRAWINGS

FIG. 1 is a block diagram of an example system including a processor and a fan according to some implementations.

FIG. 2 is a flowchart of a method for detecting an operating state of a fan cooling a processor according to some implementations.

FIG. 3 is an example of comparing temperatures of a processor and fan speeds of a fan at different times to a condition corresponding to abnormal operation of the fan, according to some implementations.

FIG. 4 is another an example of comparing temperatures of a processor and fan speeds of a fan at different times to a condition corresponding to abnormal operation of the fan, according to some implementations.

FIG. 5 is an additional example of comparing temperatures of a processor and fan speeds of a fan at different times to a condition corresponding to abnormal operation of the fan, according to some implementations.

### DETAILED DESCRIPTION

In various systems, a fan is coupled to a processor. The fan rotates at a speed to provide airflow across the processor for cooling. The processor provides control signals to the fan, with a speed at which the fan rotates (also referred to herein as a “fan speed”) changing in response to a control signal. In various implementations, the control signal from the processor is based on a temperature of the processor. For example, a control signal from the processor to the fan increases a speed at which the fan rotates when the processor temperature increases, while a different control signal from the processor to the fan decreases the speed at which the fan rotates when the processor temperature decreases.

A processor has a target operating temperature that allows the processor to provide optimal functionality and performance while preventing temperature-induced damage to the processor. Additionally, the target operating temperature allows the processor to operate without overheating a printed circuit board to which the processor is mounted to an unsafe level. One or more standards specify a maximum temperature for a printed circuit board to which a processor is mounted to maintain user safety (often referred to as a touch temperature). For example, a standard specifies that a board including a processor cannot reach 100 degrees Celsius for the board to be capable of being touched by a user.

While control signals from a processor adjust a speed at which the fan rotates, conventional close loop target temperature fan control techniques are unable to determine responses of the fan to a control signal. For example, a conventional close loop target temperature fan control technique is unable to determine whether a speed of the fan has increased or decreased as specified by a control signal. As an example in a conventional close loop technique, if the fan is blocked and unable to spin, a processor provides control signals to the fan, but is unable to determine that the fan is not rotating at a fan speed specified by the control signals.

Additionally, to account for fans having different operating characteristics being used with a processor in different configuration, conventional open loop control techniques can be utilized. In open loop control techniques, operating characteristics of a specific fan are stored for access by the processor and feedback from the fan during operation ensures the fan is operating at the speed set by the processor. The operating characteristics of the specific fan specify a temperature to speed curve, sometimes in the form of a table that includes fan speeds for different processor operating temperatures. Such fan-specific configuration increases production time for systems by having specific combinations of processor and fan identified and configured for operation with each other. Further, any change in the processor or fan in a particular system requires an entirely new fan-specific operating characteristic to be loaded into memory for use in the conventional open loop system. As such, neither close loop nor open loop techniques can operate with fan speed feedback and without fan-specific operating characteristics.

To allow a processor to identify whether a fan has a fan speed matching a control signal from the processor without manually identifying the fan to the processor, a processor maintains one or more conditions corresponding to abnormal operation of the fan. The processor detects a speed of the fan and compares the speed of the fan to the one or more conditions. In response to the speed of the fan satisfying a condition, the processor detects abnormal operation of the fan. When abnormal operation of the fan is detected, the processor reduces one or more protection temperatures. This protects the processor from thermal damage while also preventing a circuit board to which the processor is mounted from heating to an unsafe level. The reduced protection temperatures protect both the processor and a user or other components contacting the circuit board from being damaged when the fan is insufficiently cooling the processor. Additionally, comparing the speed of the fan to the one or more conditions allows abnormal operation of the fan to be detected without storing specific operating characteristics of the fan in the processor or in a memory coupled to the processor.

To that end, the present specification sets forth various implementations of a device including a fan and a processor coupled to the fan. The processor includes a system management unit configured to detect abnormal operation of the fan in response to a speed of the fan satisfying one or more conditions. In some implementations, the system management unit is further configured to reduce one or more protection temperatures including, for example, a throttling temperature and/or a shut-off temperature of the processor in response to detecting abnormal operation of the fan. In some implementations, the protection temperatures are reduced by a temperature offset. The system management unit is configured to increase the protection temperatures in response to no longer detecting abnormal operation of the fan in some implementations. In some implementations, the system management unit is configured to transmit a notification to a display device for presentation to a user, where the notification indicates detection of abnormal operation of the fan. The notification includes one or more reduced protection temperatures for the processor in some implementations.

In some implementations, detecting abnormal operation of the fan in response to the speed of the fan satisfying one or more conditions includes detecting abnormal operation of the fan in response to the speed of the fan being less than a threshold speed. In various implementations, detecting abnormal operation of the fan in response to the speed of the fan satisfying one or more conditions includes detecting abnormal operation of the fan in response to the speed of the fan being less than a threshold speed and a temperature of the processor being greater than a fan activation temperature.

In some implementations, responsive to detecting that a first temperature of the processor at a first time exceeds a threshold temperature and that a first fan speed at the first time is less than a target fan speed, the system management unit detects abnormal operation of the fan when a temperature of the processor remains above the threshold temperature during a period between the first time and a second time and a difference of a maximum fan speed during the period and the fan speed at the first time is less than a threshold speed difference. In some implementations, the threshold speed difference is predefined.

The present specification also describes various implementations of a computer program product comprising a computer readable medium comprising instructions executable to detect abnormal operation of a fan coupled to a processor in response to a speed of the processor satisfying one or more conditions. In some implementations, the instructions are also executable to reduce one or more protection temperatures of the processor in response to detecting abnormal operation of the fan. The instructions are also executable to increase the protection temperatures of the processor in response to no longer detecting abnormal operation of the fan in various implementations.

In some implementations, the instructions are executable to: responsive to detecting that a first temperature of the processor at a first time exceeds a threshold temperature and that a first fan speed at the first time is less than a target fan speed, the system management unit detects abnormal operation of the fan when a temperature of the processor remains above the threshold temperature during a period between the first time and a second time and a difference of a maximum fan speed during the period and the fan speed at the first time is less than a threshold speed difference.

The present specification also describes various implementations of a method including detecting a speed at which a fan rotates, where the fan is coupled to a processor. The method further includes detecting abnormal operation of the fan in response to the speed at which the fan rotates satisfying one or more conditions. In some implementations, the method also includes reducing one or more protection temperatures of the processor in response to detecting abnormal operation of the fan. The method also increases the protection temperatures of the processor in response to no longer detecting abnormal operation of the fan in various implementations. In some implementations, the method further includes transmitting a notification to a display device for presentation to a user, the notification indicating abnormal operation of the fan was detected.

In various implementations, detecting abnormal operation of the fan in response to the speed at which the fan rotates satisfying one or more conditions includes detecting abnormal operation of the fan in response to the speed of the fan being less than a threshold speed and a temperature of the processor being greater than a fan activation temperature. In some implementations, responsive to detecting that a first temperature of the processor at a first time exceeds a threshold temperature and that a first fan speed at the first time is less than a target fan speed, detecting abnormal operation of the fan further comprises detecting a temperature of the processor remains above the threshold temperature during a period between the first time and a second time and calculating a difference of a maximum fan speed during the period and the fan speed at the first time is less than a threshold speed difference.

In some implementations, detecting abnormal operation of the fan in response to the speed at which the fan rotates satisfying one or more conditions includes: detecting a first temperature of the processor at a first time exceeds a threshold temperature, detecting a first fan speed at the first time is less than a target fan speed, detecting a minimum temperature of the processor during a period between the first time and a second time exceeds the threshold temperature, and detecting a difference between a maximum fan speed during the period and the fan speed at the first time is less than a threshold speed difference.

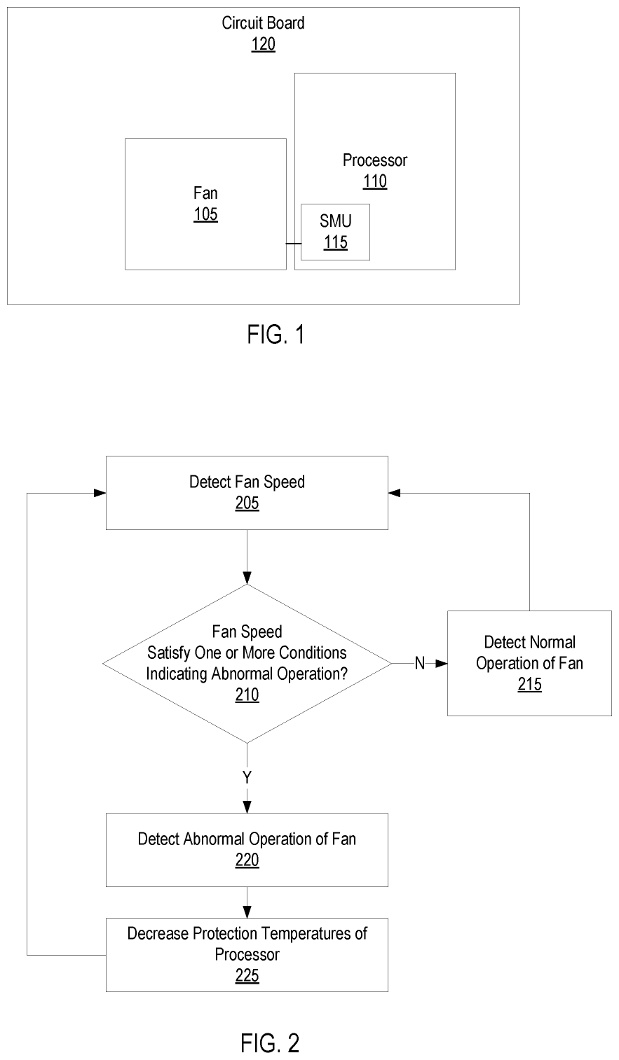

FIG. 1 is a block diagram of an example system including a fan 105 and a processor 110. In various implementations, the fan 105 and the processor 110 are coupled to a circuit board 120. The circuit board 120 is a printed circuit board (PCB) in some examples, with the circuit board 120 including conductive connections between the processor 110 and other components or between the fan 105 and other components. For example, the circuit board 120 includes conductive connections for coupling the processor 110 to another circuit board. In various implementations, the processor 110 is coupled to a surface of the circuit board 120.

The fan 105 is configured to rotate and to direct moving air across one or more surfaces of the processor 110. In various implementations, a heat sink is coupled to a surface of the processor 110, with the heat sink comprising a thermally conductive material that absorbs heat generated by the processor 110 during operation. The fan 105 moves air across the heat sink, with the moving air dissipating heat from the processor that was absorbed by the heat sink. In some implementations, the fan 105 is coupled to the heat sink.

The fan 105 is also communicatively coupled to the processor 110 and receives one or more control signals from the processor 110. In some implementations, the processor 110 includes one or more cores for executing instructions. In various implementations, the processor 110 includes a cache memory is coupled to a cache memory for retrieval of data or instructions used by the processor 110.

In some implementations, the processor 110 is a parallel accelerated processor that is particularly adapted for parallel processing and executes parallel processing tasks. For example, a parallel accelerated processor is a graphics processing unit (“GPU”) used for executing graphics processing tasks that are output to a display, a general purpose GPU (GPG) for intensively parallel processing tasks (e.g., neural network training, deep learning models, scientific computation, etc.), or other accelerated computing devices. However, in other implementations a parallel accelerated processor is configured to perform one or more operations for machine learning in parallel, one or more operations for cryptocurrency mining in parallel, or configured to perform one or more other specialized functions in parallel.

In the example shown by FIG. 1, the fan 105 is communicatively coupled to a SMU 115 (system management unit) of the processor 110. The SMU 115 monitors a temperature of the processor 110 and transmits control signals to the fan 105 based on the temperature of the processor 110. For example, the SMU 115 transmits one or more control signals to the fan 105 that increase a speed at which the fan 105 rotates in response to the SMU 115 determining a temperature of the processor 110 has increased. As another example, the SMU 115 transmits one or more control signals to the fan 105 that decrease the speed at which the fan 105 rotates in response to the SMU 115 determining the temperature of the processor has decreased. This allows the SMU 115 to adjust a speed at which the fan 105 rotates based on a determined temperature of the processor 110.

In various implementations, the SMU 115 maintains operating characteristics for the processor 110 that includes a target operating temperature for the processor 110. The target operating temperature specifies a temperature for the processor 110 to have during operation. In various implementations, the target operating temperature is stored in a memory included in the processor 110 or accessible to the processor 110. In some implementations, a user specifies the target operating temperature for the processor 110 through a configuration tool or application, allowing a user to customize the target operating temperature for the processor 110.

Additionally, the SMU 115 also includes one or more protection temperatures in some implementations. In some examples, such protection temperatures are maintained by a driver executed by the SMU. For example, the SMU 115 maintains a throttling temperature and a shut-off temperature. A throttling temperature operates as a first level of protection to delay or avoid the temperature of a processor reaching the shut-off temperature (a second level of protection). In response to the SMU 115 determining the processor 110 has a temperature equaling or exceeding the throttling temperature, the SMU 115 reduces functionality of the processor 110. The reduced functionality causes the processor 110 to generate less heat during operation, allowing the processor 110 to cool while the processor 110 remains operational but providing limited functionality. In response to determining a temperature of the processor 110 equals or exceeds the shut-off temperature, the SMU 115 shuts off the processor 110 to prevent the operating temperature of the processor from damaging the processor 110.

While the protection temperatures the SMU 115 maintains for the processor 110 mitigate temperature damage to the processor 110 from operation at elevated temperatures, heat generated by the processor 110 during operation is partially absorbed by the circuit board 120 to which the processor 110 is coupled. This causes surfaces of the circuit board 120 to heat up as the processor operates, with an increased temperature of the circuit board 120 increasing a risk of damage to other components and increasing a risk of injury to a user contacting one or more portions of the circuit board 120.

Referring to FIG. 2, a method for determining an operating state of a fan 105 cooling a processor 110 is described. In various implementations, the method is performed by a system management unit (SMU) 115 of a processor 110. Instructions for executing the method are stored in a memory coupled to the processor 110, so the processor 110 performs the steps described below when the instructions are executed.

The method detects 205 a fan speed of the fan 105. In various implementations, the fan speed is a number of revolutions per minute (RPM) at which the fan rotates. The SMU 115 of the processor 110 is communicatively coupled to the fan 105 and determines the fan speed from one or more signals received from the fan 105. In some implementations, the SMU 115 continually detects 205 the fan speed, while in other implementations, the SMU 115 detects 205 the fan speed at periodic intervals.

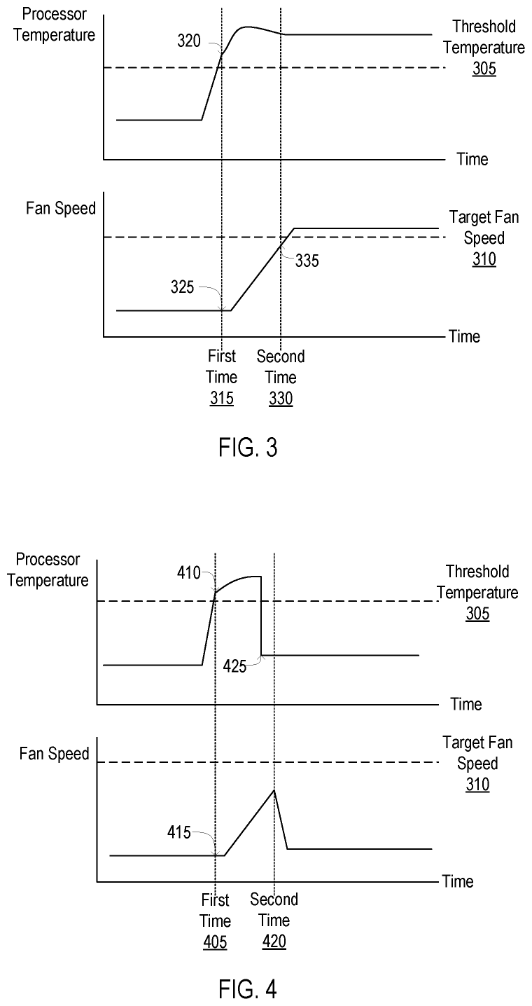

The SMU 115 maintains one or more conditions that correspond to abnormal operation of the fan 105 and compares 210 the fan speed to the one or more conditions. For example, a condition corresponding to abnormal operation of the fan 105 specifies a threshold speed of the fan. One or more of the conditions account for the fan speed as well as a temperature of the processor 110. For example, the SMU maintains a fan activation temperature for the processor 110, with the fan 105 operating when a temperature of the processor 110 equals or exceeds the fan activation temperature, and the fan 105 being shut-off when the temperature of the processor 110 is less than the fan activation temperature. Other conditions, further described below in conjunction with FIGS. 3-5 account for the fan speed at different times and the temperature of the processor 110 at different times. Accounting for the fan speed and the temperature of the processor 110 at different times allows the method to avoid any chance of false report of fan abnormality. Further, accounting for the fan speed and the temperature of the processor 110 at different times increases accuracy of identifying fan abnormality. In some instances, a processor's temperature may increase rapidly while a fan speed's response is hysteretic in nature. In this way, a processor's temperature may essentially spike quickly while the fan speed has yet to increase to a target speed. While it may appear that the fan speed is operating abnormally at that moment, the fan speed could increase in shortly thereafter and represent no abnormality. As such, accounting for fan speed and processor temperature at multiple times reduces inaccurate fan speed abnormality identifications.

In response to the fan speed not satisfying at least one of the conditions corresponding to abnormal operation of the fan 105, the method detects 215 normal operation of the fan 105. With normal operation detected 215, no control signals are transmitted to the fan and no operating characteristics of the processor 110 are modified. In various embodiments, the method continues to detect 205 the fan speed of the fan after detecting 215 normal operation of the fan 105.

However, in response to the fan speed satisfying at least of the conditions corresponding to abnormal operation of the fan 105, the method detects 220 abnormal operation of the fan 105. Abnormal operation of the fan 105 indicates the fan 105 is rotating at an insufficient speed to cool the processor 110, so the airflow across the processor 110 or a heat sink of the processor 110 from the fan is insufficient to prevent the temperature of the processor 110 from increasing. In an example, the method detects 220 abnormal operation of the fan 105 in response to the detected fan speed being less than a threshold speed.

In other examples, one or more conditions corresponding to abnormal operation of the fan 105 account for a speed of the fan and a temperature of the processor 110. For example, the SMU 115 maintains a fan activation temperature with the fan 105 operating when a temperature of the processor 110 equals or exceeds the fan activation temperature, while the fan 105 is shut-off when the temperature of the processor 110 is less than the fan activation temperature. In the preceding example, the method detects 220 abnormal operation of the fan in response to the temperature of the processor 110 equaling or exceeding the fan activation temperature and the detected fan speed being less than a threshold speed maintained by the SMU 115.

In some implementations, one or more conditions corresponding to abnormal operation of the fan 105 account for fan speeds detected 205 at different times and temperatures of the processor 110 detected at different times. For example, a condition corresponding to abnormal operation of the fan 105 specifies that a first temperature of the processor at a first time exceeds a threshold temperature, a first fan speed of the fan 105 at the first time is less than a target fan speed, a minimum temperature of the processor 110 during a period between the first time and a second time exceeds the threshold temperature, and a difference between a maximum fan speed during the period and the fan speed at the first time is less than a threshold speed difference. Accounting for temperatures of the processor 110 at different times and fan speeds of the fan 105 at different times, as described above, prevents the method from falsely detecting abnormal operation of the fan 105 by accounting for delays between changes in a temperature of the processor 110 and changes in a fan speed of the fan 105, allowing the method to account for variations in processor usage affecting the temperature of the processor 110.

FIG. 3 shows an example of comparing temperatures of a processor 110 and fan speeds of a fan 105 at different times to a condition corresponding to abnormal operation of the fan 105. In the example of FIG. 3, the condition corresponding to abnormal operation of the fan 105 identifies abnormal operation of the fan 105 when: (1) a first temperature of the processor 110 at a first time exceeds a threshold temperature, (2) a first fan speed of the fan 105 at the first time is less than a target fan speed, (3) a minimum temperature of the processor 110 during a period between the first time and a second time exceeds the threshold temperature, and (4) a a maximum fan speed during the period and the fan speed at the first time is less than a threshold speed difference.

FIG. 3 shows a graph of the temperature of the processor 110 over time and a graph of the fan speed of the fan 105 over time. The graph of the temperature of the processor 110 over time identifies a threshold temperature 305 of the processor 110, while the graph of the fan speed over time depicts a target fan speed 310. In various implementations, a memory coupled to or included in the processor 110 includes the threshold temperature 305 and the target fan speed 310. In some implementations, input from a user is received to specify the threshold temperature 305 or the target fan speed 310.

In the example of FIG. 3, at a first time 315, the processor 110 has temperature 320, which exceeds the threshold temperature 305. For example, temperature 320 corresponds to the processor 110 beginning execution of a particular application or beginning execution of a particular function, causing an increase resource consumption by the processor. However, at time 315, the fan 105 is rotating at fan speed 325, which is less than the target fan speed 310. As temperature 320 reflects an increase in the temperature of the processor 110, the fan speed 325 is expected to increase as well, providing increased cooling to the processor 110. However, the fan speed 325 has a hysteresis relative to the temperature of the processor 110, causing the fan speed 325 to increase after the temperature of the processor 110 increases. Without accounting for this temporal delay between an increase in the temperature of the processor 110 and the fan speed of the fan 105, the fan 105 would be detected to be abnormally operating at time 315.

To account for the delay between temperature increase and corresponding fan speed increase, in response to temperature 320 exceeding the threshold temperature 305 and in response to fan speed 325 being less than the target fan speed 310 at the first time 315, the temperature of the processor 110 is monitored during a period between the first time 315 and a second time 330. In some implementations, the first time 315 and the second time 330 are separated by a predefined interval, such as 5 seconds. Different time intervals separating the first time 315 and the second time 330 may be specified in different implementations.

The SMU 115 of the processor 110 identifies a minimum temperature of the processor 110 during the period from the first time 315 to the second time 330. In the example of FIG. 3, temperature 320 at the first time 315 is the minimum temperature of the processor 110 from the first time 315 to the second time 330. The SMU 115 compares the minimum temperature of the processor 110 to the threshold temperature 305. In the example, of FIG. 3, the minimum temperature of the processor 110, temperature 320, exceeds the threshold temperature 305. This indicates that the processor 110 has operated above the threshold temperature 305 during the period between the first time 315 and the second time 330.

In response to the processor 110 operating above the threshold temperature 305 during the period between the first time 315 and the second time 330, the SMU 115 identifies a maximum fan speed during the period between the first time 315 and the second time 330. In the example of FIG. 3, the maximum fan speed during the period is fan speed 335 occurring at the second time 330. The SMU 115 determines a difference between maximum fan speed during the period (fan speed 335) and the fan speed at the first time 315 (fan speed 325). The SMU 115 compares the determined difference between the maximum fan speed and the fan speed 325 at the first time 315 to a threshold speed difference stored by the SMU 115. Comparing the difference between the maximum fan speed and the fan speed at the first time 315 to the threshold speed difference, accounts for a rate at which the fan speed changes, allowing the comparison to reflect a relative change in fan speed. This allows the comparison to be performed for different fans with different operating speeds without the SMU 115 maintaining or retrieving specific operating characteristics for individual fans 105, simplifying evaluation of fan operation across a wider range of fans. In response to the difference between the maximum fan speed and the fan speed 325 at the first time 315 being less than the threshold speed difference, the SMU 115 detects abnormal operation of the fan 105. That is, a difference that is less than the threshold speed difference indicates that the fan speed has not increased as rapidly as expected while the temperature of the processor 110 remained above the threshold temperature 305. However, in response to the difference between the maximum fan speed and the fan speed at the first time 315 equaling or exceeding the threshold speed difference, the SMU 115 detects normal operation of the fan 105, as the fan speed has increased at least as rapidly as expected to cool the processor 110 while the temperature of the processor 110 remained above the threshold temperature 305 during the period between the first time 315 and the second time 330.

FIG. 4 sets forth another example of comparing temperatures of a processor 110 and fan speeds of a fan 105 at different times to a condition corresponding to abnormal operation of the fan 105. In the example of FIG. 4, the condition corresponding to abnormal operation of the fan 105 identifies abnormal operation of the fan 105 when: (1) a first temperature of the processor 110 at a first time exceeds a threshold temperature, (2) a first fan speed of the fan 105 at the first time is less than a target fan speed, (3) a minimum temperature of the processor 110 during a period between the first time and a second time exceeds the threshold temperature, and (4) a difference between a maximum fan speed during the period and the fan speed at the first time is less than a threshold speed difference.

Similar to FIG. 3, FIG. 4 shows a graph of the temperature of the processor 110 over time and a graph of the fan speed of the fan 105 over time. The graph of the temperature of the processor 110 over time identifies a threshold temperature 305 of the processor 110, while the graph of the fan speed over time depicts a target fan speed 310. In the example of FIG. 4, at a first time 405, the processor 110 has temperature 410, which exceeds the threshold temperature 305. Also at the first time 405, the fan 105 rotates at fan speed 415, which is less than the target fan speed 310.

As further described above in conjunction with FIG. 3, to account for a delay in the fan speed changing as the temperature of the processor 110 changes, the temperature of the processor 110 is monitored between the first time 405 and a second time 420. During the period between the first time 405 and the second time 420, the SMU 115 identifies a minimum temperature of the processor 110. In the example of FIG. 4, temperature 425 is the minimum temperature of the processor 110 between the first time 405 and the second time 420. The SMU 115 compares the minimum temperature of the processor 110 to the threshold temperature 305. In the example of FIG. 4, the minimum temperature of the processor 110 between the first time 405 and the second time 420 (temperature 425) does not exceed the threshold temperature 305. This indicates that the processor 110 has not sustained an operating temperature above the threshold temperature 305 during the period between the first time 405 and the second time 420. For example, the temperature of the processor 110 shown in FIG. 4 corresponds to the processor 110 starting to execute an application or a function that is computationally intensive and the application or the function stopping after a short interval, causing resource consumption by the processor 110 to decrease. The reduction in resource consumption causes the temperature of the processor 110 to decrease below the threshold temperature 305. With the minimum temperature of the processor 110 between the first time 405 and the second time 420 below the threshold temperature 305, the SMU does not further evaluate the fan speed between the first time 405 and the second time 420 and determines the fan 105 is operating normally. This prevents the SMU 115 from falsely detecting abnormal operation of the fan 105 by accounting for changes in the temperature of the processor 110 and changes in the fan speed of the fan 105 over a time interval that accounts for varying temperature of the processor 110 and varying fan speed of the fan 105 over time.

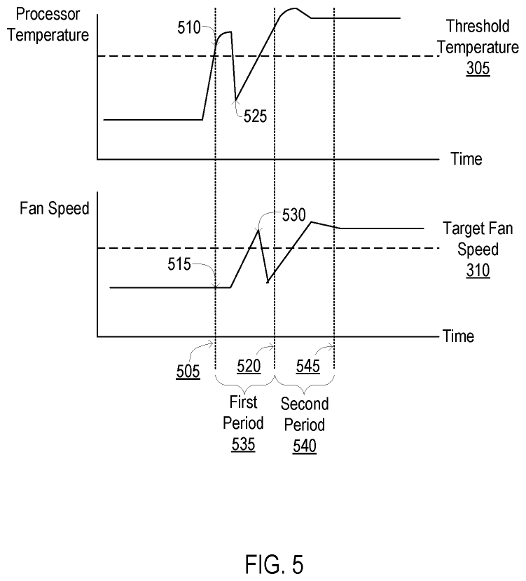

FIG. 5 shows another example of comparing temperatures of a processor 110 and fan speeds of a fan 105 at different times to a condition corresponding to abnormal operation of the fan 105. FIG. 5 sets forth a graph of the temperature of the processor 110 over time and a graph of the fan speed of the fan 105 over time. The graph of the temperature of the processor 110 over time identifies a threshold temperature 305 of the processor 110, while the graph of the fan speed over time depicts a target fan speed 310. In the example of FIG. 5, at a first time 505 of a first period 535 of time, the processor 110 has temperature 510, which exceeds the threshold temperature 305. Also at the first time 505, the fan 105 rotates at fan speed 515, which is less than the target fan speed 310.

As further described above in conjunction with FIGS. 3 and 4, to account for a delay in the fan speed changing as the temperature of the processor 110 changes, the temperature of the processor 110 is monitored during the first period 535 between the first time 505 and a second time 520. During the first period 535, the SMU 115 of the processor 110 identifies a minimum temperature 525 of the processor 110. The SMU 115 compares the minimum temperature 525 of the processor 110 to the threshold temperature 305. In the example of FIG. 5, the minimum temperature of the processor 110 during the first period 535, does not exceed the threshold temperature 305. This indicates that the processor 110 did not sustain an operating temperature above the threshold temperature 305 during the first period 535. For example, the temperature of the processor 110 over time shown in FIG. 5 corresponds to the processor 110 starting to execute an application or a function that is computationally intensive and the application or the function stopping after a short interval, causing resource consumption by the processor 110 to decrease, then starting another computationally intensive application that increases the temperature of the processor 110.

As the minimum temperature of the processor 110 during the first period 535 does not exceed the threshold temperature 305 in the example of FIG. 5, the SMU 115 of the processor 110 need not make any further determination as the fan is deemed to be operating normally. during the same period 535. This is true even in the case where the maximum fan speed 530 during the first period 535 exceeds the target fan speed 310.

FIG. 5 also includes a second time period that begins at time 520 and ends at time 545. The processor temperature at the beginning of the second period 540 exceeds the threshold temperature 305 and the fan speed at that time is less than the target fan speed 310. To determine whether the fan is operating abnormally during this period, the SMU monitors the processor temperature and fan speed over the second period 540. The processor temperature exceeds the threshold temperature 305 during the second period 540. The fan speed increases during the second time period and the difference between the maximum fan speed during the second time period and the fan speed at the beginning of the second time period exceeds a threshold speed difference. As such, the SMU determines that the fan is operating normally. The particular scenario depicted in FIG. 5 may occur when a processor begins to execute computationally intensive instructions just before the beginning of the first time period, quickly ends execution during the first time period, and before expiration of the first time period, again begins execution of computationally intensive instructions and maintains execution for some time (the second time period and others). At various single points of time, the fan may appear to be operating abnormally, but when periods of time and rates of change of fan speed are taken into account, the fan is seen to be operating normally.

As shown in the examples of FIGS. 3-5, accounting for temperatures of the processor 110 during a time interval between a first time and a second time as well as fan speeds of the fan 105 during the time interval prevents transient changes in a temperature of the processor 110 or delays in the fan speed of the fan 105 in response to change in the temperature of the processor 110 from causing identification of abnormal operation of the fan 105. This provides a conservative approach to determining fan operating abnormalities, reduces false identifications of fan operating abnormalities, and allows a more accurate evaluation of operation of the fan that accounts for variations in computational resources used by the processor 110 and that accounts for latency in a change in temperature of the processor 110 causing a change in the fan speed of the fan 105.

Referring back to FIG. 2, in response to detecting 220 abnormal operation of the fan from the detected fan speed satisfying one or more of the conditions corresponding to abnormal operation of the fan 105, the method reduces 225 one or more protective temperatures (such as a throttling temperature and a shut-off temperature) of the processor 110. As further described above in conjunction with FIG. 1, a throttling temperature for a processor 110 specifies a temperature that reduces functionality provided by the processor 110 when reached. This reduction in functionality reduces computational actions performed by the processor 110, decreasing heat generated by the processor 110 during operation. When the fan is abnormally operating, air flow from the fan across the processor 110 is reduced, decreasing effectiveness of the fan in cooling the processor 110. This reduction in cooling from the fan causes the processor 110 to operate at a hotter temperature, which radiates heat to other components, such as a circuit board 120 to which the fan 105 and the processor 110 are coupled. Reducing 225 the throttling temperature causes the processor 110 to reduce computational actions at a lower temperature than the throttling temperature stored for the processor 110. This allows the processor 110 to compensate, to a degree, for reduced cooling provided by an abnormally operating fan 105 by generating less heat when operating. Such a reduction in heat generation by the processor provides increased protection from thermal damage of the processor. Additionally, a reduction in heat generation by the processor reduces heat that other components absorb from the processor and reduces an amount by which surfaces of a circuit board 120 increase in temperature from operation of the processor 110 when the fan 105 is abnormally operating. Such reduction in heat generation through throttling may in some instances, not be enough to completely protect the processor or other components from thermal damage. In such instances, a processor is shut-off completely. The temperature at which the processor is shut-off is referred to as the shut-off temperature. As mentioned above, if the fan is determined to be operating abnormally, both the throttling temperature and the shut-off temperature may be reduced. Such a reduction in shut-off temperature ensures that the processor's temperature will not cause the components and PCB to overheat above a safe temperature.

In some implementations, in response to detecting 220 abnormal operation of the fan from the detected fan speed satisfying one or more of the conditions corresponding to abnormal operation of the fan 105, the method presents a notification to a user. For example, the SMU 115 of the processor 110 (through a driver, for example) transmits a notification to a display device that is coupled to the processor 110 for display to a user. The notification includes a message indicating that abnormal operation of the fan 105 was detected. In some implementations, the notification also identifies the reduced protection temperatures such as a reduced throttling temperature and/or reduced shut down temperature for the processor 110.

To reduce 225 the protection temperatures for the processor 110, the method reduces 225 a stored throttling temperature and shut-off temperature for the processor 110 by a temperature offset stored by the SMU 115. For example, the temperature offset is 10 degrees Celsius, so the SMU 115 reduces 225 the protection temperatures for the processor 110 by 10 degrees Celsius in response to detecting 220 abnormal operation of the fan 105. In some implementations, the offset for throttling temperature is different than that of the shut-off temperature. In some implementations, a user specifies the temperature offset through a configuration application or a configuration tool, with the SMU 115 using the user-specified temperature offset to reduce 225 the protection temperatures for the processor 110.

With the protection temperatures of the processor 110 reduced 225, the method continues to detect 205 the fan speed of the fan 105 and determining 210 whether the detected fan speed indicates abnormal operation of the fan 105. While the detected fan speed satisfies at least one of the conditions indicating abnormal operations, the protection temperatures of the processor 110 remain reduced 225. In response to the detected fan speed not satisfying at least one of the conditions, the method increases the protection temperatures of the processor 110 to a default value. This allows the protection temperatures of the processor 110 to be dynamically adjusted when normal operation of the fan 105 is detected 215. In some implementations, a notification is presented to the user when the protection temperatures of the processor 110 are increased.

In view of the explanations set forth above, readers will recognize that a processor detecting a fan speed of a fan cooling the processing and detecting abnormal operation of the fan based on the fan speed satisfying one or more conditions allows the processor to be more quickly protected from temperature-induced damage. As abnormal operation of the fan results in reduced air flow across the processor or across a heat-sink of the processor, abnormal operation of the fan impairs dissipation of heat generated by the processor during operation. Additionally, such detection of abnormal operation of the fan allows operation of the processor to be modified to slow temperature increase of the processor, which slows temperature increase of a circuit board to which the processor is coupled from operation of the processor. This slowing of heating of the circuit board by the processor when the fan is abnormally operating prevents the circuit board from reaching a temperature that could injure a user or damage other components. In implementations where abnormal operation of the fan is detected over a period of time utilizing processor temperature and rates of change of fan speed, abnormal operation of the fan is conservatively determined and false reports of fan abnormality are reduced.

It will be understood from the foregoing description that modifications and changes can be made in various implementations of the present disclosure. The descriptions in this specification are for purposes of illustration only and are not to be construed in a limiting sense. The scope of the present disclosure is limited only by the language of the following claims.

What is claimed is:

1. A device comprising:
a fan; and
a processor coupled to the fan, the processor including a system management unit configured to detect abnormal operation of the fan in response to a speed of the fan satisfying one or more conditions.

2. The device of claim 1, wherein the system management unit is further configured to:
reduce one or more protection temperatures of the processor in response to detecting abnormal operation of the fan.

3. The device of claim 2, wherein the system management unit is further configured to:
increase the protection temperatures of the processor in response to no longer detecting abnormal operation of the fan.

4. The device of claim 2, wherein the protection temperatures of the processor are reduced by a predefined temperature offset.

5. The device of claim 1, wherein the abnormal operation of the fan is detected in response to the speed of the fan being less than a threshold speed.

6. The device of claim 1, wherein the abnormal operation of the fan is detected in response to the speed of the fan being less than a threshold speed and a temperature of the processor being greater than a fan activation temperature.

7. The device of claim 1, wherein, responsive to detecting that a first temperature of the processor at a first time exceeds a threshold temperature and that a first fan speed at the first time is less than a target fan speed, the system management unit detects abnormal operation of the fan when:
a temperature of the processor remains above the threshold temperature during a period between the first time and a second time; and
a difference of a maximum fan speed during the period and the fan speed at the first time is less than a threshold speed difference.

8. The device of claim 7, wherein the threshold speed difference is predefined.

9. The device of claim 1, wherein the system management unit is further configured to:
transmit a notification to a display device for presentation to a user, the notification indicating detection of abnormal operation of the fan.

10. The device of claim 9, wherein the notification includes one or more reduced protection temperatures for the processor.

11. A computer program product comprising a computer readable medium, the computer readable medium comprising instructions executable to:
detect abnormal operation of a fan coupled to a processor in response to a speed of the fan satisfying one or more conditions.

12. The computer program product of claim 11, further comprising instructions executable to:
reduce one or more protection temperatures of the processor in response to detecting abnormal operation of the fan.

13. The computer program product of claim 12, further comprising instructions executable to:
increase the protection temperatures of the processor in response to no longer detecting abnormal operation of the fan.

14. The computer program product of claim 11, further comprising instructions executable to:
responsive to detecting that a first temperature of the processor at a first time exceeds a threshold temperature and that a first fan speed at the first time is less than a target fan speed, the detect abnormal operation of the fan when:
a temperature of the processor remains above the threshold temperature during a period between the first time and a second time; and
a difference of a maximum fan speed during the period and the fan speed at the first time is less than a threshold speed difference.

15. A method comprising:
detecting a speed at which a fan rotates, the fan coupled to a processor; and
detecting abnormal operation of the fan in response to the speed at which the fan rotates satisfying one or more conditions.

16. The method of claim 15, further comprising:
reducing one or more protection temperatures of the processor in response to determining abnormal operation of the fan.

17. The method of claim 16, further comprising:
increasing the protection temperatures of the processor in response to no longer detecting abnormal operation of the fan.

18. The method of claim 16, wherein detecting abnormal operation of the fan in response to the speed at which the fan rotates satisfying one or more conditions comprises:
detecting abnormal operation of the fan in response to the speed of the fan being less than a threshold speed and a temperature of the processor being greater than a fan activation temperature.

19. The method of claim 16, wherein, responsive to detecting that a first temperature of the processor at a first time exceeds a threshold temperature and that a first fan speed at the first time is less than a target fan speed, detecting abnormal operation of the fan further comprises:
detecting that a temperature of the processor remains above the threshold temperature during a period between the first time and a second time; and
calculating that a difference of a maximum fan speed during the period and the fan speed at the first time is less than a threshold speed difference.

20. The method of claim 16, further comprising:
transmitting a notification to a display device for presentation to a user, the notification indicating abnormal operation of the fan was detected.
